(19) United States
(12) Patent Application Publication
(10) Pub. No.: US 2025/0119331 A1
(43) Pub. Date: Apr. 10, 2025

(54) WEIGHTING WINDOW CONFIGURATION METHODS FOR WIRELESS SIGNALS

(71) Applicant: ZTE Corporation, Shenzhen (CN)

(72) Inventors: Yihua MA, Shenzhen (CN); Zhifeng YUAN, Shenzhen (CN); Shuqiang XIA, Shenzhen (CN); Guanghui YU, Shenzhen (CN); Liujun HU, Shenzhen (CN); Chuangxin JIANG, Shenzhen (CN); Zhiqiang HAN, Shenzhen (CN)

(21) Appl. No.: 18/987,164

(22) Filed: Dec. 19, 2024

Related U.S. Application Data
(63) Continuation of application No. PCT/CN2022/139043, filed on Dec. 14, 2022.

(51) Int. Cl. H04L 27/26

(52) U.S. Cl. CPC H04L 27/2602; H04L 27/2614

(57) ABSTRACT

This patent application discloses methods, apparatus, and systems that relate to weighting window configuration design that can be used in ISAC or other wireless communication systems. In one example aspect, a method for wireless communication includes generating, by a first wireless device, a first signal from a sequence, generating, by the first wireless device, a second signal through an operation comprising multiplying the first signal with a plurality of weighting coefficients associated with a window function; and transmitting, by the first wireless device, the second signal.

### CROSS-REFERENCE TO RELATED APPLICATIONS

This application is a continuation of International Patent Application No. PCT/CN2022/139043, filed on Dec. 14, 2022, the disclosure of which is incorporated herein by reference in its entirety.

### TECHNICAL FIELD

This patent document is related to wireless communication and sensing.

### BACKGROUND

Mobile telecommunication technologies are moving the world toward an increasingly connected and networked society. In comparison with the existing wireless networks, next generation systems and communication techniques will need to support a much wider range of use-case characteristics and provide a more complex and sophisticated range of access requirements and flexibilities.

### SUMMARY

This patent document discloses techniques, among other things, related to processing signals in the transmitting side through adding a window function in either an Integrated Sensing and Communication (ISAC) system or other wireless communication systems.

In one example aspect, a wireless communication method is disclosed. The method includes generating, by a first wireless device, a first signal from a sequence, generating, by the first wireless device, a second signal through an operation comprising multiplying the first signal with a plurality of weighting coefficients associated with a window function; and transmitting, by the first wireless device, the second signal.

In yet another example aspect, a wireless communication device comprising a process that is configured or operable to perform the above-described methods is disclosed.

In yet another example aspect, a computer readable storage medium is disclosed. The computer-readable storage medium stores code that, upon execution by a processor, causes the processor to implement an above-described method.

### BRIEF DESCRIPTION OF THE DRAWINGS

FIGS. 1-4 show diagrams of examples involving generating and communicating windowed signals in wireless communication systems.

FIG. 5 shows a diagram of an example involving generating windowed signals in time domain.

FIG. 6 shows a diagram of an example involving generating windowed signals in frequency domain.

FIG. 7 shows a diagram of examples involving generating windowed signals in time domain.

FIG. 8 shows an exemplary block diagram of a hardware platform that may be a part of a network device or a communication device.

FIG. 9 shows an example of network communication including a base station (BS) and user equipment (UE) based on some implementations of the disclosed technology.

FIGS. 10-11 are flowcharts representation of methods for wireless communication in accordance with one or more embodiments of the present technology.

### DETAILED DESCRIPTION

Headings for the various sections below are used to facilitate the understanding of the disclosed subject matter and do not limit the scope of the claimed subject matter in any way. Accordingly, one or more features of one section can be combined with one or more features of another section. Furthermore, 6G or ISAC terminology is used for clarity of explanation. Still, the techniques disclosed in the present document are not limited to 6G or ISAC technology only and may be used in wireless systems that implement other protocols.

As a popular 6G technology, ISAC is expected to add considerable value to the wireless communication system. The widely deployed communication infrastructures can be enhanced to provide radar services like traffic control and surveillance, drone detection, and railway obstacle detection. The various mobile communication devices in the scenarios of autonomous driving, smart home, and health care can also realize ISAC.

The communication system and radar system utilize electromagnetic waves in two different ways. The idea of dual-function design can be traced back to the 1960s. It has attracted more and more research attention in recent years, and there are many driving factors, including (1) the spectrum has been well exploited for two separate systems, and the joint spectrum utilization is expected to improve the efficiency and flexibility; (2) the hardware designs both have a technology trend of multiple antennas and digital baseband, and the share of hardware saves the cost; (3) the information fusion and mutual reinforcement of two functions bring performance gain, especially for autonomous vehicles.

The sensing function highly depends on the receiving Signal-to-Noise ratio (SNR). Windows can be added to both signal transmission and signal receiving sides, which creates a matched filtering processing with a synthetic window. This matched filtering processing scheme can maximize the receiving SNR. This scheme can also be applied for a single pulse to add the range window or multiple pulses to add the doppler window. The range window added in the time domain for a single pulse may lead to a peak to average power ratio (PAPR) problem. One solution to the PAPR problem is to use digital pre-distortion (DPD) methods. Alternatively, a range window can be added in the frequency domain when the Orthogonal Frequency-division Multiplexing (OFDM) based range measurement method is used.

The reference and synchronization signals in communication systems are usually transmitted without adding any window. On the receiver side, a receiver can add a window to suppress the sidelobe power. This processing method is not optimal for maximizing the SNR.

The proposed methods and schemes in the current application are beneficial to maximize the SNR in communication systems by adding window functions on both the transmitting and receiving sides.

The details of the proposed methods will be discussed in the following embodiments.

### Embodiment 1

This section discloses, among other things, examples of generating and transmitting a windowed signal between wireless node/devices.

Here, a wireless node can be a base station (BS); a wireless device can be a user equipment (UE).

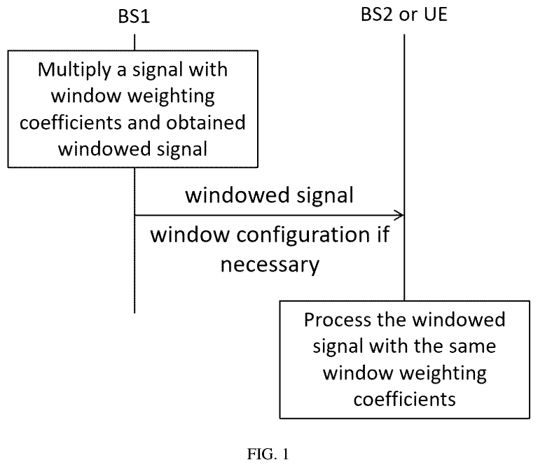

In one example, as shown in FIG. 1, a BS can generate a windowed signal through multiplying a pseudo-random sequence signal with window weighting coefficients. The pseudo-random sequence c (n) of length M_{PN}, where n=0, 1, . . . , M_{PN}−1, is defined by

$$c ( n ) = ( {x}_{1} ( n + {N}_{C} ) + {x}_{2} ( n + {N}_{C} ) ) mod 2$$

$${x}_{1} ( n + 31 ) = ( {x}_{1} ( n + 3 ) + {x}_{1} ( n ) ) mod 2$$

$${x}_{2} ( n + 31 ) = ( {x}_{2} ( n + 3 ) + {x}_{2} ( n + 2 ) + {x}_{2} ( n + 1 ) + {x}_{2} ( n ) ) mod 2$$

where N_{C}=1600 and the first m-sequence x₁(n) shall be initialized with x₁(0)=1, x₁(n)=0, n=1, 2, . . . , 30. The initialization of the second m-sequence, x₂(n), is denoted by cᵢₙᵢₜ=Σᵢ₌³⁰x²(i)·2ⁱ with the value depending on the application of the sequence.

In one example, the weighting coefficients can be square roots of values generated by a window function.

The window function can be of different types. For example, the window function can be 1) a B-spline window, 2) a polynomial window, 3) a cosine-sum window, 4) an adjustable window, or 5) a hybrid window.

In one example, the window function can be a Hanning window, a Hamming window, a Blackman window, a Kaiser window, or a Chebyshev window.

The window function can be of a fixed type. In other words, both the sender and the receiver know the type of the selected window function. Accordingly, under certain scenarios, there is no need to transmit the window function related parameters.

According to FIG. 1, the BS may transmit the windowed signal to another wireless node, e.g., a BS or a UE.

In this process, the BS can also send a window configuration information. For example, if the window has adjustable parameters, the first BS can transmit the window related parameters to the second BS or the UE.

In one example, the window configuration information can be sent together with the windowed signal. In another example, the window configuration information can be sent before or after the windowed signal. If the window configuration is sent before the windowed signal, it can be sent together with the resource allocation information of the windowed signal.

After receiving the windowed signal, the receiving side node can conduct an operation based on the windowed signal. For example, as an example shown in FIG. 1, the BS1 can process the windowed signal using the same window weighting coefficients. This process may maximize the SNR at the receiver node and increase the accuracy and efficiency of the wireless communication systems.

### Embodiment 2

This section discloses, among other things, examples of generating and transmitting a windowed signal to sensing targets that send back echo signals.

In one example, a BS sends a processed signal to sensing targets and receives echo signal(s) sending from the sensing targets. The BS can utilize the echo signal to calculate the position and velocity information of targets through delay, angle, or Doppler frequency estimation.

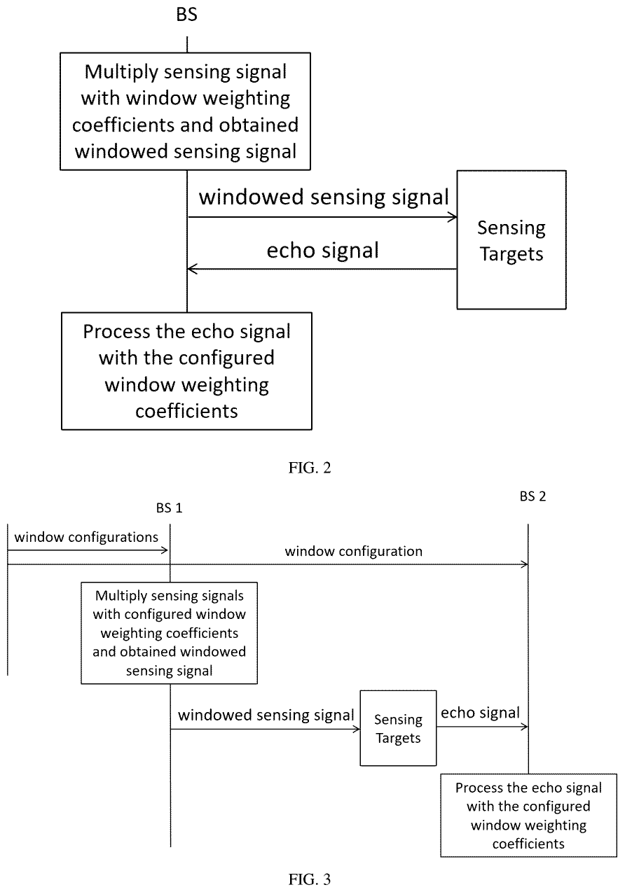

For example, as shown in FIG. 2, a BS may generate a windowed sensing signal through multiplying a low-PAPR sequence signal with window weighting coefficients. The low PAPR sequence can be generated by a low-PAPR sequency generation method, e.g., Zadoff-Chu sequence generation method.

Here, the weighting coefficients can be square roots of values generated by a window function.

The window function can be of different types. For example, the window function can be 1) a B-spline window, 2) a polynomial window, 3) a cosine-sum window, 4) an adjustable window, or 5) a hybrid window.

In one example, the window function can be a Hanning window, a Hamming window, a Blackman window, a Kaiser window, or a Chebyshev window.

The window function can be of a fixed type. In other words, both the sender and the receiver know the type of the selected window function. In certain scenarios, there is no need to transmit the window function related parameters.

The BS may transmit the windowed signal to a sensing target that may send back an echo signal. In some examples, the sensing target will not conduct further processing operation on the received windowed signal and merely sends the received signal, i.e., echo signal, back to the transmitting node. The echo signal, although not processed by the sensing targets, contain certain information related to the communication environment, e.g., distance, time, or velocity information. That information can further be extracted and utilized by the receiver of the echo signal.

After receiving the echo signal, the receiver side node can conduct an operation based on the windowed signal. For example, as an example shown in FIG. 2, the BS can process the received echo signal using the same window weighting coefficients. This process can optimize the SNR at the receiver and increase the accuracy and efficiency of the wireless communication systems.

### Embodiment 3

This embodiment discloses, among other things, multiple examples involving generating/receiving window configurations that can be used in the previous disclosed embodiments.

As disclosed in the above embodiments, the transmitting side may generate a windowed signal based on weighting coefficients related to a window function. The signal before adding window is generated by a pseudo-random sequence generation method, a low-PAPR sequency generation method, or a chirp sequence generation method. The weighting coefficients can be achieved through multiple sources, e.g., 1) configure from a higher layer, 2) configure from other wireless devices, 3) adopt a default setting according to standard specifications, or 4) generate within the device.

In one example, a higher layer, e.g., a core network (CN), may configure and transmit weighting coefficients to a wireless device/node. As disclosed in FIG. 3, a CN transmits a window configuration information to BS 1 and BS 2.

The configuration information may include window function related information, such as the weighting coefficients.

Here, the weighting coefficients can be square roots of values generated by a window function.

The window function can be of different types. For example, the window function can be 1) a B-spline window, 2) a polynomial window, 3) a cosine-sum window, 4) an adjustable window, or 5) a hybrid window.

In one example, the window function can be a Hanning window, a Hamming window, a Blackman window, a Kaiser window, or a Chebyshev window.

The window function can be of a fixed function. In other words, both the sender and the receiver know the type of the selected window function. In certain scenarios, there is no need to transmit the window function related parameters.

According to FIG. 3, the BS then transmits the windowed signal to another wireless node, e.g., a sensing target. In this example, the sensing target further backscatter an echo signal to BS2.

After receiving the echo signal, the receiver side node, e.g., BS2 can conduct an operation based on the received echo signal. For example, as an example shown in FIG. 3, the receiver node can process the windowed signal using the same window weighting coefficients. This process can optimize the SNR at the receiver, e.g., BS2, and increase the accuracy and efficiency of the wireless communication systems.

A wireless node/device can set the weighting coefficients by conducting an operation. For example, a wireless device/node may generate weighting coefficients based on an internal process without receiving them from an outside source.

The weighting coefficients can also be set with default values. For example, a wireless device/node may adopt weighting coefficients based on default settings without receiving from an outside source or generating through an internal operation.

### Embodiment 4

This embodiment discloses, among other things, multiple examples involving generating/receiving window configurations that can be used in the previous disclosed embodiments.

As disclosed in the above embodiments, the transmitting side may generate a windowed signal based on weighting coefficients related to a window function. The signal before adding window is generated by a pseudo-random sequence generation method, a low-PAPR sequency generation method, or a chirp sequence generation method. The weighting coefficients can be achieved through multiple sources, e.g., 1) configure from a higher layer, 2) configure from other wireless devices, 3) adopt a default setting according to standard specifications, or 4) generate within the device.

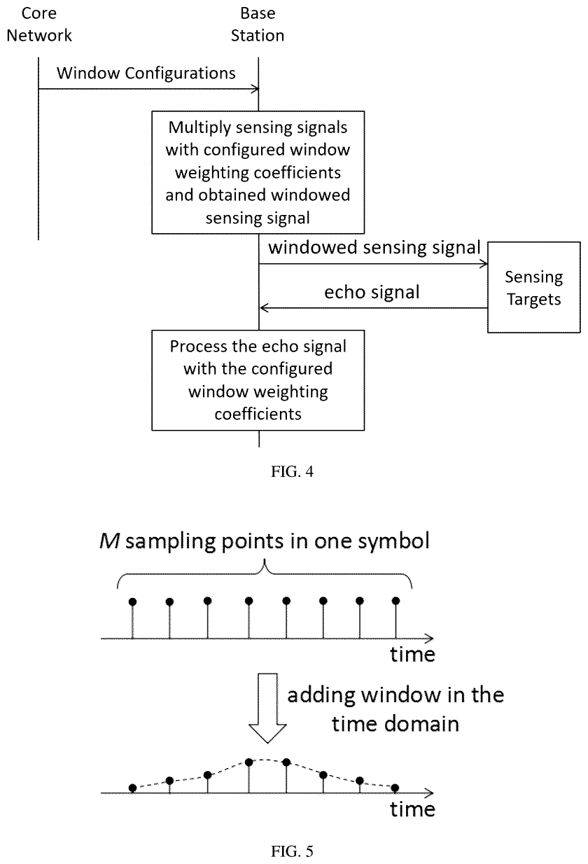

In one example, a higher layer, e.g., a core network (CN), may send weighting coefficients to a wireless device/node. As disclosed in FIG. 4, a CN transmits a window configuration information to a BS. The configuration information may include window function related information, such as the weighting coefficients.

Here, the weighting coefficients can be square roots of values generated by a window function.

The window function can be of different types. For example, the window function can be 1) a B-spline window, 2) a polynomial window, 3) a cosine-sum window, 4) an adjustable window, or 5) a hybrid window.

In one example, the window function can be a Hanning window, a Hamming window, a Blackman window, a Kaiser window, or a Chebyshev window.

The window function can be a fixed function. In other words, both the sender and the receiver know the type of the selected window function. In certain scenarios, there is no need to transmit the window function related parameters.

The window function can also be non-fixed, as shown in FIG. 4. The window configuration information may include further information to indicate the window function. For example, an index can be included in the window configuration information to indicate a selected window function among different windows. The index can be generated from a list/database known to the wireless device/node involved in the communication.

The window configuration information may also include an index to indicate whether the window function operation is conducted in the transmitting side.

In one example, a window on/off indicator can be included in the window configuration information that is transmitted from a CN to a BS to indicate whether the window function operation should be conducted at the transmitter side.

In another example, a window on/off indicator can be included in the window configuration information that is transmitted from BS1 to BS2 to indicate whether the window function operation was conducted at the transmitter side.

The window configuration information may also include some adjustable parameters for an adjustable window function.

The BS receives the configuration information and multiplies a sensing signal with the configured window coefficients. Then, the BS transmits the windowed sensing signal out. As shown in a particular example in FIG. 4, the sensing signals arrive at the sensing targets and the corresponding echo signals propagate to the receive antennas of the BS. The BS processes the echo signal according to the window configuration information. This process can optimize the SNR at the receiver, e.g., BS2, and increase the accuracy and efficiency of the wireless communication systems.

A wireless node/device can set the weighting coefficients by conducting an operation. For example, a wireless device/node may generate weighting coefficients based on an internal process without receiving them from an outside source.

The weighting coefficients can also be set with default values. For example, a wireless device/node may adopt weighting coefficients based on default settings without receiving from an outside source or generating through an internal operation.

### Embodiment 5

This embodiment discloses, among other things, examples involving generating, based on weighting coefficients, windowed signals that can be used in the previously disclosed embodiments.

The weighting coefficients can be added in either the time or frequency domain.

For example, FIG. 5 discloses how the weighting coefficients can be added to a signal in the time domain.

Note that the pre-processed signal in FIG. 5 is used as an illustration example. The proposed processing scheme can be used in other types of signals.

As shown in FIG. 5, the original signal is an M sampling point in one orthogonal frequency-division multiplexing (OFDM) symbol. The M sampling points can be generated by M sub-carriers using Inverse Fast Fourier Transform (IFFT). In transmission, there is usually an oversampling, meaning more than M sampling points are transmitted. This example in FIG. 5 focuses only on the M sampling points instead of all the sampling points since the oversampling points can be determined by M points.

In FIG. 5, the M sampling points are multiplied with an M-length window weighting coefficient and transferred to a windowed signal. In this example, the windowing process helps to decrease the sidelobe power level of range Fast Fourier Transform (FFT). It reduces the processing SNR loss using time-domain processing with the same window.

### Embodiment 6

This embodiment discloses, among other things, examples involving generating, based on weighting coefficients, windowed signals that can be used in the previously disclosed embodiments.

The weighting coefficients can be added in either the time or frequency domain.

This embodiment shows how the weighting coefficients can be added in the frequency domain.

This embodiment shows how the weighting coefficients are added intra the pulse in the frequency domain.

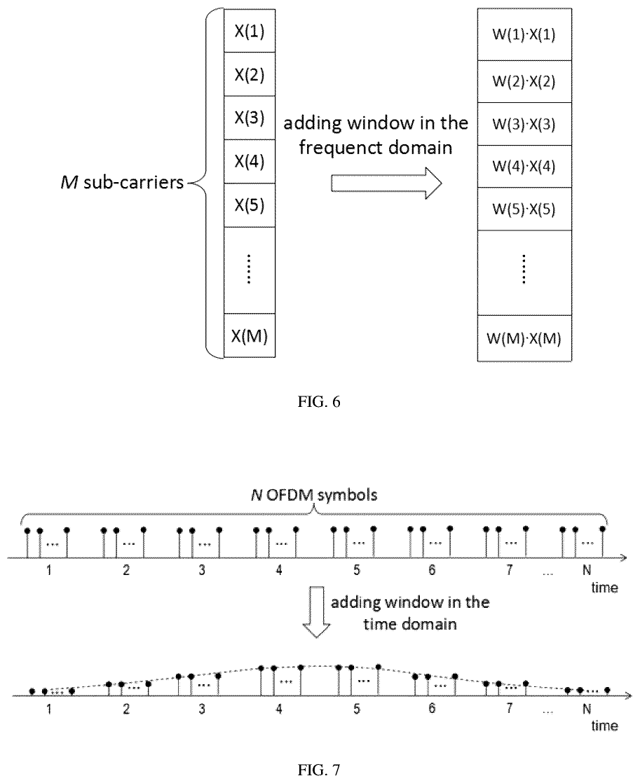

The original signal in the example shown in FIG. 6 is M sub-carriers in one OFDM symbol.

Note that the pre-processed signal in FIG. 6 is used as an illustration example. The proposed processing scheme can be used in other types of signals.

As shown in FIG. 6, the M sampling points are multiplied with an M-length window weighting coefficient to generate a windowed signal.

In this example, the windowing processing helps to decrease the sidelobe power level of range FFT and reduces the processing SNR loss using frequency-domain processing with the same window.

### Embodiment 7

This embodiment discloses among other things, examples involving generating, based on weighting coefficients, windowed signals that can be used in the previous disclosed embodiments.

The weighting coefficients can be added in either the time or frequency domain.

This embodiment shows how the weighting coefficients can be added in time domain.

For example, as shown in FIG. 7, a window function is added to inter pulses in the time domain.

Note that the pre-processed signal in FIG. 7 is used as an illustration example. The proposed processing scheme can be used in other types of signals.

The original signal in example shown in FIG. 7 is N OFDM symbols and M sub-carriers in one OFDM symbol.

As shown in FIG. 7, the N OFDM symbols are multiplied with an N-length window weighting coefficients to generate a windowed signal.

In this example, the windowing processing may help to decreases the sidelobe power level of Doppler FFT and reduces the processing SNR loss using Doppler-domain processing with the same window.

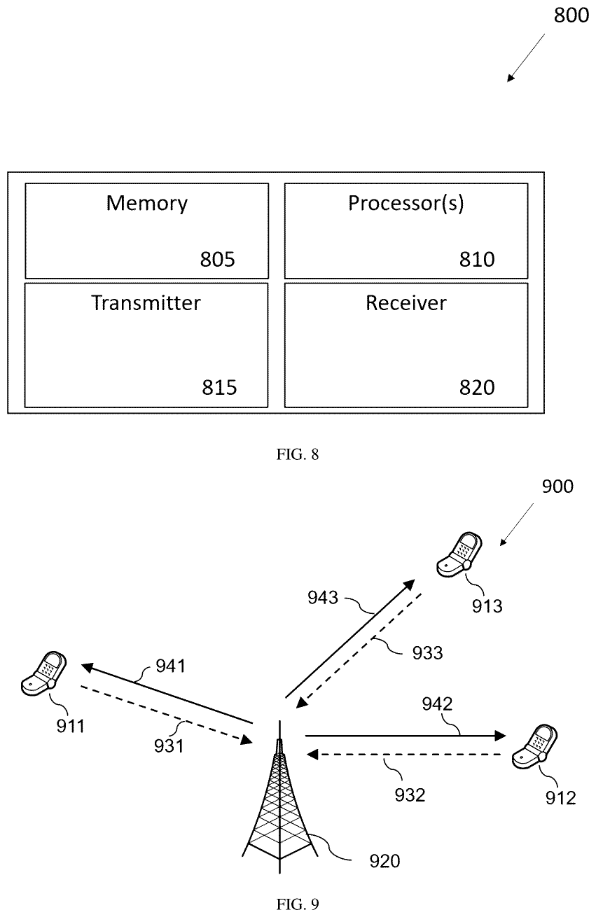

FIG. 8 shows an exemplary block diagram of a hardware platform 800 that may be a part of a network device (e.g., base station) or a communication device (e.g., a user equipment (UE)). The hardware platform 800 includes at least one processor 810 and a memory 805 having instructions stored thereupon. The instructions upon execution by the processor 810 configure the hardware platform 800 to perform the operations described in FIGS. 1 to 7 and in the various embodiments described in this patent application document. The transmitter 815 transmits or sends information or data to another device. For example, a network device transmitter can send a message to user equipment. The receiver 820 receives information or data transmitted or sent by another device. For example, user equipment can receive a message from a network device.

The implementations as discussed above will apply to a network communication. FIG. 9 shows an example of a communication system (e.g., a 6G or NR cellular network) that includes a base station 920 and one or more user equipment (UE) 911, 912 and 913. In some embodiments, the UEs access the BS (e.g., the network) using a communication link to the network (sometimes called uplink direction, as depicted by dashed arrows 931, 932, 933), which then enables subsequent communication (e.g., shown in the direction from the network to the UEs, sometimes called downlink direction, shown by arrows 941, 942, 943) from the BS to the UEs. In some embodiments, the BS send information to the UEs (sometimes called downlink direction, as depicted by arrows 941, 942, 943), which then enables subsequent communication (e.g., shown in the direction from the UEs to the BS, sometimes called uplink direction, shown by dashed arrows 931, 932, 933) from the UEs to the BS. The UE may be, for example, a smartphone, a tablet, a mobile computer, a machine to machine (M2M) device, an Internet of Things (IoT) device, and so on.

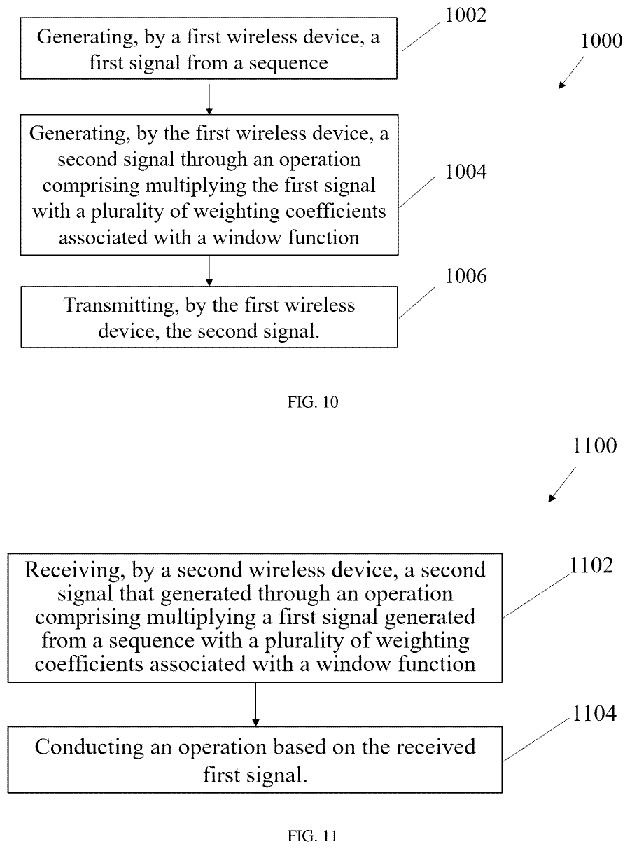

FIG. 10 shows an example flowchart representation of a method for wireless communication in accordance with one or more embodiments of the present technology. Operation 1002 includes generating, by a first wireless device, a second signal through an operation comprising multiplying a first signal with a plurality of weighting coefficients associated with a window function. Operation 1004 includes transmitting, by the first wireless device, the second signal,

FIG. 11 show an example flowchart representation of a method for wireless communication in accordance with one or more embodiments of the present technology. Operation 1102 includes receiving, by a second wireless device, a second signal that generated through an operation comprising multiplying a first signal with a plurality of weighting coefficients associated with a window function. Operation 1104 includes conducting an operation based on the received first signal.

Various preferred embodiments and additional features of the above-described method of FIGS. 10-11 are as follows. Further examples are described with reference to embodiments 1 to 7.

In one example aspect, a wireless communication method is disclosed. The method includes generating, generating, by a first wireless device, a first signal from a sequence, generating, by the first wireless device, a second signal through an operation comprising multiplying the first signal with a plurality of weighting coefficients associated with a window function; and transmitting, by the first wireless device, the second signal.

In another example aspect, another wireless communication method is disclosed. The method includes receiving, by a second wireless device, a second signal that generated through an operation comprising multiplying a first signal generated from a sequence with a plurality of weighting coefficients associated with a window function; and conducting an operation based on the received first signal.

In some embodiments, the sequence is generated based on at least one of 1) a pseudo-random sequence generation method, 2) a low-PAPR sequence generation method, or 3) a chirp sequence generation method.

In some embodiments, the weighting coefficients are determined based on a configuration information transmitted from a higher layer.

In some embodiments, the first signal comprises at least one of: 1) a wireless sensing signal, 2) a reference signal, or 3) a synchronization signal.

In some embodiments, the operation is conducted in at least one of 1) time domain or 2) frequency domain

In some embodiments, the weighting coefficients comprise at least one of 1) one time-domain sequence bit 2) one time-domain sampling points 3) one sub-carrier, 4) a plurality of time-domain sequence bits, 5) a plurality of time-domain sampling points, or 6) a plurality of sub-carriers.

In some embodiments, at least one of the weight coefficients is a square root of a value determined by the window function.

In some embodiments, the window function is of a type that is at least one of 1) a B-spline window, 2) a polynomial window, 3) a cosine-sum window, 4) an adjustable window, or 5) a hybrid window.

In some embodiments, the window function is at least one of 1) a Hanning window, 2) a Hamming window, 3) a Blackman window, 4) a Kaiser window, or 5) a Chebyshev window.

In some embodiments, the window function is a fixed function.

In some embodiments, the configuration information comprises an index indicating a window function, wherein the index is selected from a list comprising indexes of different windows function, wherein an index of a rectangle window indicates a configuration of no window.

In some embodiments, the configuration information includes a parameter indicating whether the operation is conducted.

In some embodiments, the configuration information includes at least one adjustable parameter of the window function.

In some embodiments, the above disclosed methods further comprising transmitting the configuration information, by the first wireless device, to another wireless node.

In some embodiments, the configuration information is transmitted together with the second signal.

In some embodiments, the configuration information is transmitted before transmitting the second signal.

In some embodiments, the above disclosed methods further comprising conducting a second operation on the second signal, wherein the second operation comprises multiplying the second signal with the weighting coefficients.

It will be appreciated that the present document discloses methods and apparatus related to weighting window configuration design that can be used in ISAC or other wireless communication systems. Although ISAC attracts attention in academic area, none of the existing study for ISAC or other communication system, covers the configuration scheme involving adding a weighting window in the transmitting side to optimize the SNR in the receiving side. This patent application discloses multiple solutions regarding 1) how a weighting window related information can be configured and transmitting within a communication system and 2) how a weighting window can be added to a signal to generate a windowed signal. The proposed methods and schemes will improve the communication efficiency and accuracy in ISAC and other wireless communication system due to at least avoiding SNR loss.

The disclosed and other embodiments, modules and the functional operations described in this document can be implemented in digital electronic circuitry, or in computer software, firmware, or hardware, including the structures disclosed in this document and their structural equivalents, or in combinations of one or more of them. The disclosed and other embodiments can be implemented as one or more computer program products, i.e., one or more modules of computer program instructions encoded on a computer readable medium for execution by, or to control the operation of, data processing apparatus. The computer readable medium can be a machine-readable storage device, a machine-readable storage substrate, a memory device, a composition of matter effecting a machine-readable propagated signal, or a combination of one or more of them. The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. A propagated signal is an artificially generated signal, e.g., a machine-generated electrical, optical, or electromagnetic signal, that is generated to encode information for transmission to suitable receiver apparatus.

A computer program (also known as a program, software, software application, script, or code) can be written in any form of programming language, including compiled or interpreted languages, and it can be deployed in any form, including as a standalone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this document can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

While this document contains many specifics, these should not be construed as limitations on the scope of an invention that is claimed or of what may be claimed, but rather as descriptions of features specific to particular embodiments. Certain features that are described in this document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or a variation of a subcombination. Similarly, while operations are depicted in the drawings in a particular order, this should not be understood as requiring that such operations be performed in the particular order shown or in sequential order, or that all illustrated operations be performed, to achieve desirable results.

Only a few examples and implementations are disclosed. Variations, modifications, and enhancements to the described examples and implementations and other implementations can be made based on what is disclosed.

I/We claim:

1. A method for wireless communication comprising:
generating, by a first wireless node, a first signal from a sequence,
generating, by the first wireless node, a second signal through an operation comprising multiplying the first signal with weighting coefficients associated with a window function, wherein at least one of the weighting coefficients is a square root of a value determined by the window function, and
wherein the weighting coefficients are determined based on a configuration information transmitted from a higher layer to the first wireless node; and
transmitting, by the first wireless node, the second signal.

2. The method of claim 1, wherein the sequence is generated based on at least one of 1) a pseudo-random sequence generation method, 2) a low-PAPR sequence generation method, or 3) a chirp sequence generation method.

3. The method of claim 1, wherein the weighting coefficients comprise at least one of 1) one time-domain sequence bit 2) one time-domain sampling points 3) one sub-carrier, 4) a plurality of time-domain sequence bits, 5) a plurality of time-domain sampling points, or 6) a plurality of sub-carriers.

4. The method of claim 1, wherein the window function is of a type that is at least one of 1) a B-spline window, 2) a polynomial window, 3) a cosine-sum window, 4) an adjustable window, or 5) a hybrid window.

5. The method of claim 1, wherein the configuration information comprises an index indicating a window function, wherein the index is selected from a list comprising indexes of different window functions, wherein an index of a rectangle window indicates a configuration of no window.

6. A method for wireless communication comprising:
receiving, by a second wireless node from a first wireless node, a second signal that is generated through an operation comprising multiplying a first signal generated from a sequence with weighting coefficients associated with a window function, wherein at least one of the weighting coefficients is a square root of a value determined by the window function, and
wherein the weighting coefficients are determined based on a configuration information transmitted from a higher layer to the first wireless node; and
conducting an operation based on the second signal.

7. The method of claim 6, wherein the sequence is generated based on at least one of 1) a pseudo-random sequence generation method, 2) a low-PAPR sequence generation method, or 3) a chirp sequence generation method.

8. The method of claim 6, wherein the weighting coefficients comprise at least one of 1) one time-domain sequence bit 2) one time-domain sampling points 3) one sub-carrier, 4) a plurality of time-domain sequence bits, 5) a plurality of time-domain sampling points, or 6) a plurality of sub-carriers.

9. The method of claim 6, wherein the window function is of a type that is at least one of 1) a B-spline window, 2) a polynomial window, 3) a cosine-sum window, 4) an adjustable window, or 5) a hybrid window.

10. The method of claim 6, wherein the configuration information comprises an index indicating a window function, wherein the index is selected from a list comprising indexes of different window functions, wherein an index of a rectangle window indicates a configuration of no window.

11. An apparatus for wireless communication comprising a processor and a memory storing instructions, execution of which by the processor causes the apparatus to:
generate a first signal from a sequence,
generate a second signal through an operation comprising multiplying the first signal with weighting coefficients associated with a window function, wherein at least one of the weighting coefficients is a square root of a value determined by the window function, and
wherein the weighting coefficients are determined based on a configuration information transmitted from a higher layer to the apparatus; and
transmit the second signal.

12. The apparatus of claim 11, wherein the sequence is generated based on at least one of 1) a pseudo-random sequence generation method, 2) a low-PAPR sequence generation method, or 3) a chirp sequence generation method.

13. The apparatus of claim 11, wherein the weighting coefficients comprise at least one of 1) one time-domain sequence bit 2) one time-domain sampling points 3) one sub-carrier, 4) a plurality of time-domain sequence bits, 5) a plurality of time-domain sampling points, or 6) a plurality of sub-carriers.

14. The apparatus of claim 11, wherein the window function is of a type that is at least one of 1) a B-spline window, 2) a polynomial window, 3) a cosine-sum window, 4) an adjustable window, or 5) a hybrid window.

15. The apparatus of claim 11, wherein the configuration information comprises an index indicating a window function, wherein the index is selected from a list comprising indexes of different window functions, wherein an index of a rectangle window indicates a configuration of no window.

16. An apparatus for wireless communication comprising a processor and a memory storing instructions, execution of which by the processor causes the apparatus to:
receive, from a first wireless node, a second signal that is generated through an operation comprising multiplying a first signal generated from a sequence with weighting coefficients associated with a window function, wherein at least one of the weighting coefficients is a square root of a value determined by the window function, and
wherein the weighting coefficients are determined based on a configuration information transmitted from a higher layer to the first wireless node; and
conducting an operation based on the second signal.

17. The apparatus of claim 16, wherein the sequence is generated based on at least one of 1) a pseudo-random sequence generation method, 2) a low-PAPR sequence generation method, or 3) a chirp sequence generation method.

18. The apparatus of claim 16, wherein the weighting coefficients comprise at least one of 1) one time-domain sequence bit 2) one time-domain sampling points 3) one sub-carrier, 4) a plurality of time-domain sequence bits, 5) a plurality of time-domain sampling points, or 6) a plurality of sub-carriers.

19. The apparatus of claim 16, wherein the window function is of a type that is at least one of 1) a B-spline window, 2) a polynomial window, 3) a cosine-sum window, 4) an adjustable window, or 5) a hybrid window.

20. The apparatus of claim 16, wherein the configuration information comprises an index indicating a window function, wherein the index is selected from a list comprising indexes of different window functions, wherein an index of a rectangle window indicates a configuration of no window.
